(19) United States
(12) Patent Application Publication
(10) Pub. No.: US 2026/0025996 A1
(43) Pub. Date: Jan. 22, 2026

(54) VERTICAL CONTACT FOR DIELECTRIC GAS REGIONS BETWEEN BIT LINE STRUCTURES

(71) Applicant: Micron Technology, Inc., Boise, ID (US)

(72) Inventors: Sidhartha GUPTA, Boise, ID (US); Shyam SURTHI, Boise, ID (US)

(21) Appl. No.: 19/214,790

(22) Filed: May 21, 2025

Related U.S. Application Data
(60) Provisional application No. 63/672,113, filed on Jul. 16, 2024.

(51) Int. Cl. H10B 43/27; H10B 41/27

(52) U.S. Cl. CPC H10B 43/27; H10B 41/27

(57) ABSTRACT

Embodiments described herein relate to various structures, integrated assemblies, and memory devices. In some embodiments, an apparatus includes a first bit line structure and a hard mask structure that is directly on the first bit line structure. The apparatus includes a second bit line structure and an elongated, vertically-oriented contact structure that is directly on the second bit line structure. The apparatus includes an elongated, vertically-oriented dielectric gas region that is between the first bit line structure and the second bit line structure and that includes an upper end region that overlaps the hard mask structure and the elongated, vertically-oriented contact structure.

### CROSS-REFERENCE TO RELATED APPLICATION

This Patent Application claims priority to U.S. Provisional Patent Application No. 63/672, 113, filed on Jul. 16, 2024, entitled “VERTICAL CONTACT FOR DIELECTRIC GAS REGIONS BETWEEN BIT LINE STRUCTURES,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a vertical contact for dielectric gas regions between bit line structures.

### BACKGROUND

Memory devices provide data storage for electronic systems. Flash memory is a type of non-volatile memory, meaning that the memory retains data in the absence of a power supply. As an example, an electronic device may use flash memory in a solid state drive (SSD) for non-volatile storage of information, rather than a hard disk drive that uses magnetic disks for storage. NAND is a type of flash memory that has advantages over hard disk drives, such as lower erase times, lower write times, and less chip area per memory cell, which allows for more storage density and lower cost. The memory cells in NAND memory may be configured or formed in vertical stacks. This arrangement is sometimes called vertical NAND or three-dimensional (3D) NAND. 3D NAND arrangements enable a greater quantity of memory cells per chip surface area because of the vertical stacking of memory cells. 3D NAND arrangements also enable more options for the placement of cells to avoid interference and electron leakage, which can improve memory device performance. As the demand for storage capacity and performance increases, improvements in NAND architecture and improved methods for fabricating NAND memory are desirable.

### BRIEF DESCRIPTION OF THE DRAWINGS

FIG. 1 is a diagram illustrating an example of components included in a memory device described herein.

FIG. 2 is a diagram illustrating an example of a NAND memory array described herein.

FIG. 3 is a diagram illustrating an example of a 3D NAND memory array described herein.

FIGS. 4A and 4B are diagrammatic views related to an example memory device structure described herein.

FIG. 5 is a flowchart of an example method of forming an integrated assembly or memory device having an interconnect region that includes a contact structure described herein.

FIG. 6 is a flowchart of an example method of forming an integrated assembly or memory device having an interconnect region that includes a contact structure described herein.

FIGS. 7A through 7D are diagrammatic views showing formation of portions of an interconnect region that includes a contact structure described at stages of an example process described herein.

### DETAILED DESCRIPTION

NAND memory devices often include a three-dimensional layering of word line structures and bit line structures proximate to memory cells to increase a density or a memory capacity of the NAND memory device. “Three-dimensional layering,” also known as 3D layering or vertical layering, refers to a design or construction technique where the word line structures and bit line structures may be stacked or arranged in multiple layers to achieve higher density or performance compared to planar (e.g., two-dimensional or 2D) arrangements. By selectively activating appropriate word line structures and bit line structures in the 3D layering, individual memory cells within the NAND memory device may be accessed for reading or programming operations.

The NAND memory device may have dielectric gas regions (e.g., air gaps) between adjacent bit line structures. Each dielectric gas region may serve as a dielectric barrier or a shielding barrier that prevents electrical interference, parasitic degradation, or crosstalk between adjacent bit structures. The dielectric gas regions may be between surfaces of the adjacent bit line structures, where the surfaces are facing each other across a gap or separation. If the dielectric gas includes air, the dielectric gas regions may be referred to as air gaps. The presence of the dielectric gas regions contributes to enhanced reliability and performance of the NAND memory device, ensuring that a memory cell can be accurately selected so that data can be read from and written to the memory cell without interference between adjacent bit line structures.

Contact structures that connect with the bit line structures are traditionally laterally-oriented within the memory device. However, laterally-oriented contact structures may inhibit layout of the integrated circuitry (e.g., for an advanced product such as wafer-to-wafer (W2W) or stacked die product), constrain a length of the dielectric gas regions, increase an overall signaling length to increase parasitic degradation (e.g., unintended capacitance, inductance, or resistance) of the memory device, and increase a footprint of the memory device.

Some embodiments described herein include a semiconductor device with vertically-oriented contact structures that connect with bit line structures. In these embodiments, the semiconductor device (e.g., a NAND memory device) with the vertically-oriented contact structures may enable a layout of integrated circuitry and may facilitate an extension in a length of the dielectric gas regions or a decrease in an overall signaling length to reduce parasitic degradation in the memory device or an advanced product using the memory device. Additionally, or alternatively, a footprint of the memory device may be reduced.

Through the extension of length of the dielectric gas regions and the decrease in the overall signaling length, the embodiments may improve reliability or performance relative to another semiconductor device formed using laterally-oriented contact structures and having dielectric gas regions of shorter lengths. By improving the reliability or the performance, the embodiments may reduce an amount of resources used to support a market consuming the semiconductor device (e.g., labor, semiconductor manufacturing tools, raw materials, or computing resources).

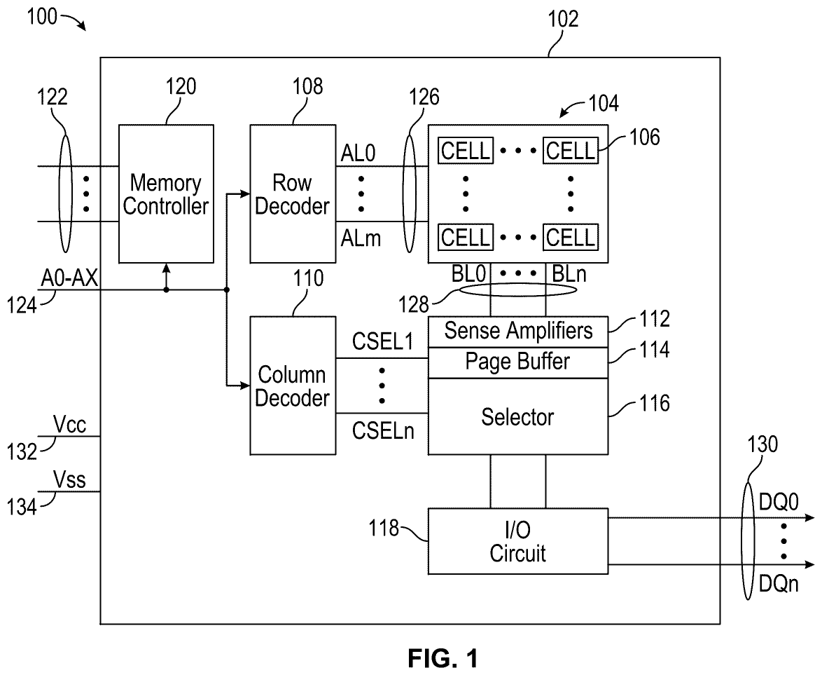

FIG. 1 is a diagram illustrating an example 100 of components included in a memory device 102 described herein. The memory device 102 may include a memory array 104 having multiple memory cells 106. The memory device 102 may include one or more components (e.g., circuits) to transmit signals to or perform memory operations on the memory array 104. For example, the memory device 102 may include a row decoder 108, a column decoder 110, one or more sense amplifiers 112, a page buffer 114, a selector 116, an input/output (I/O) circuit 118, and a memory controller 120.

The memory controller 120 may control memory operations of the memory device 102 according to one or more signals received via one or more control lines 122, such as one or more clock signals or control signals that indicate an operation (e.g., write, read, or erase) to be performed. The memory controller 120 may determine one or more memory cells 106 upon which the operation is to be performed based on one or more signals received via one or more address lines 124, such as one or more address signals (shown as A0-AX). A host device external from the memory device 102 may control the values of the control signals on the control lines 122 or the address signals on the address line 124.

The memory device 102 may use access lines 126 (sometimes called word lines or row lines, and shown as AL0-ALm) and bit lines 128 (sometimes called digit lines, data lines, or column lines, and shown as BL0-BLn) to transfer data to or from one or more of the memory cells 106. For example, the row decoder 108 and the column decoder 110 may receive and decode the address signals (A0-AX) from the address line 124 and may determine which of the memory cells 106 are to be accessed based on the address signals. The row decoder 108 and the column decoder 110 may provide signals to those memory cells 106 via one or more access lines 126 and one or more bit lines 128, respectively.

For example, the column decoder 110 may receive and decode address signals into one or more column select signals (shown as CSEL1-CSELn). The selector 116 may receive the column select signals and may select data in the page buffer 114 that represents values of data to be read from or to be programmed into memory cells 106. The page buffer 114 may be configured to store data received from a host device before the data is programmed into relevant portions of the memory array 104, or the page buffer 114 may store data read from the memory array 104 before the data is transmitted to the host device. The sense amplifiers 112 may be configured to determine the values to be read from or written to the memory cells 106 using the bit lines 128. For example, in a selected string of memory cells 106, a sense amplifier 112 may read a logic level in a memory cell 106 in response to a read current flowing through the selected string to a bit line 128. The I/O circuit 118 may transfer values of data into or out of the memory device 102 (e.g., to or from a host device), such as into or out of the page buffer 114 or the memory array 104, using I/O lines 130 (shown as (DQ0-DQn)).

The memory controller 120 may generate or receive positive and negative supply signals, such as a supply voltage (Vcc) 132 and a negative supply (Vss) 134 (e.g., a ground potential), from an external source or power supply (e.g., an internal battery, an external battery, or an AC-to-DC converter).

As indicated above, FIG. 1 is provided as an example. Other examples may differ from what is described with regard to FIG. 1.

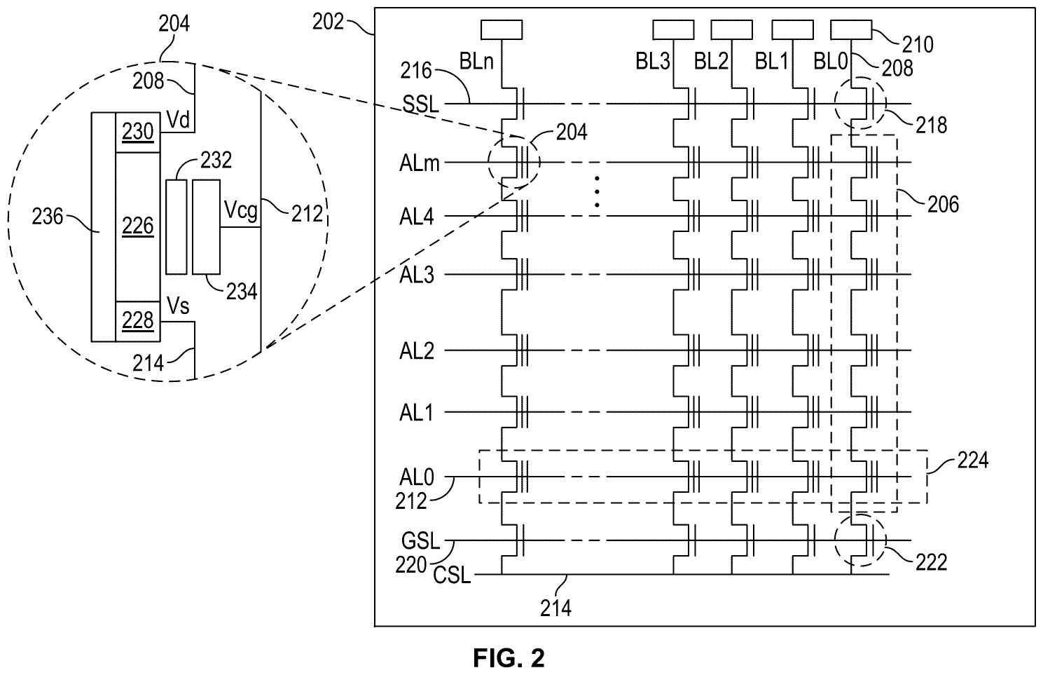

FIG. 2 is a diagram illustrating an example 200 of a NAND memory array 202 described herein. The NAND memory array 202 may correspond to the memory array 104 described above in connection with FIG. 1. The memory array 202 may be part of a three-dimensional stack of memory arrays, such as 3D NAND flash memory.

The memory array 202 includes multiple memory cells 204. A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 (sometimes called a string) may include multiple memory cells 204 connected in series. A NAND string 206 is coupled to a bit line 208 (sometimes called a digit line or a column line, and shown as BL0-BLn). Data can be read from or written to the memory cells 204 of a NAND string 206 via a corresponding bit line 208 using one or more input/output (I/O) components 210 (e.g., an I/O circuit, an I/O bus, a page buffer, or a sensing component, such as a sense amplifier). Memory cells 204 of different NAND strings 206 (e.g., one memory cell 204 per NAND string 206) may be coupled with one another via access lines 212 (sometimes called word lines or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some implementations (e.g., for single-level cells), the memory cells 204 connected to an access line 212 may be associated with a single page of memory. In some implementations (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation).

In some implementations, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). A memory device may store a data state in the memory cell 204 by charging the floating gate 232 to a particular voltage associated with the data state or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Veg may be supplied from an access line 212, and a source voltage Vs may be supplied via the common source line 214 (which, in some implementations, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states, so that all of the other memory cells 204 in the NAND string 206 conduct, and the I/O component 210, can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block or a subset of memory cells of the block.

As indicated above, FIG. 2 is provided as an example. Other examples may differ from what is described with regard to FIG. 2.

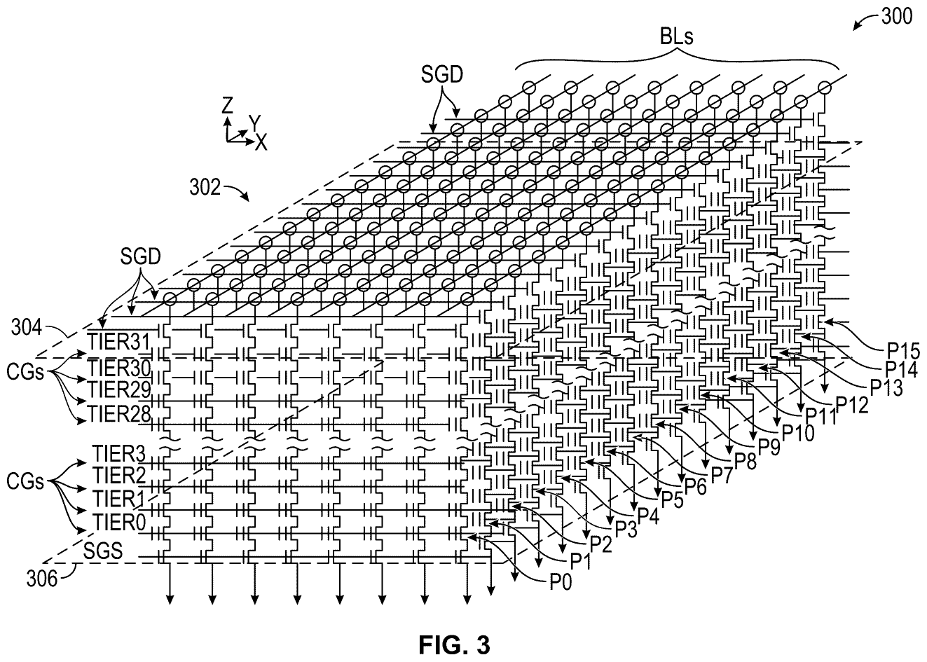

FIG. 3 is a diagram illustrating an example 300 of a 3D NAND memory array 302 described herein. The 3D NAND memory array 302 may correspond to the memory array 104 described above in connection with FIG. 1 or the NAND memory array 202 described above in connection with FIG. 2.

The 3D NAND memory array 302 includes multiple strings of memory cells. A string includes multiple tiers of charge storage transistors stacked in a first direction, shown as the Z direction. The charge storage transistors are stacked source-to-drain from a source-side select gate (SGS) to a drain-side select gate (SGD). In the example 300 of FIG. 3, each string includes 32 tiers (shown as TIER0 through TIER31). In other examples, each string of memory cells may include a different quantity of tiers (e.g., 8tiers, 16 tiers, 64 tiers, or 128 tiers). The memory cells of a particular string may share a common channel region, such as one formed in a respective pillar of semiconductor material (e.g., polysilicon) about which the string of memory cells is formed.

Along a second direction, shown as the Y direction, multiple strings of memory cells are connected along bit lines (BLs). For example, a first group of strings is coupled to a first bit line extending in the second direction, a second group of strings is coupled to a second bit line extending in the second direction, and so on.

Along a third direction, shown as the X direction, memory cells in the same tier but in different strings are arranged in memory pages (shown as P0 through P15). For example, a group of memory cells in a tier may be coupled to the same access line to form a page (or multiple pages, in the example of multi-level cells). Within a page, each tier represents a row of memory cells, and each string of memory cells represents a column. A block of memory cells can include multiple pages, such as 128 pages or 384 pages.

Each memory cell includes a control gate (CG) coupled to an access line, as described above in connection with FIG. 2. The access line collectively couples the control gates of memory cells in a specific tier or a portion of a tier. A tier in the 3D NAND memory array 302 can be accessed or controlled using an access line. For example, the 3D NAND memory array 302 may include a first level of semiconductor material 304 (e.g., polysilicon) that couples the control gates of each memory cell in TIER31. Similar respective levels of metal or semiconductor material may couple the control gates for each respective tier. As further shown, the 3D NAND memory array 302 may include a second level of semiconductor material 306 that couples the source-side select gates (SGS) of the array. Specific strings of memory cells in the 3D NAND memory array 302 can be accessed, selected, or controlled using a combination of bit lines and select gates, and specific memory cells at one or more tiers in the specific strings can be accessed, selected, or controlled using one or more access lines.

As indicated above, FIG. 3 is provided as an example. Other examples may differ from what is described with regard to FIG. 3. For example, the number of memory cells, strings, tiers, bit lines, access lines, or pages may be greater than or less than those shown in FIG. 3.

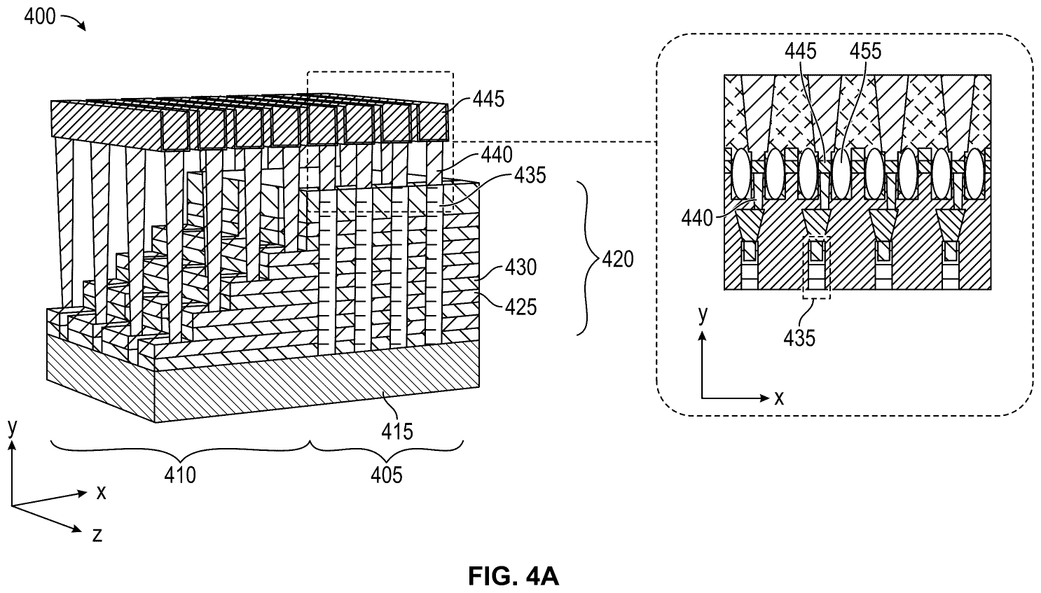

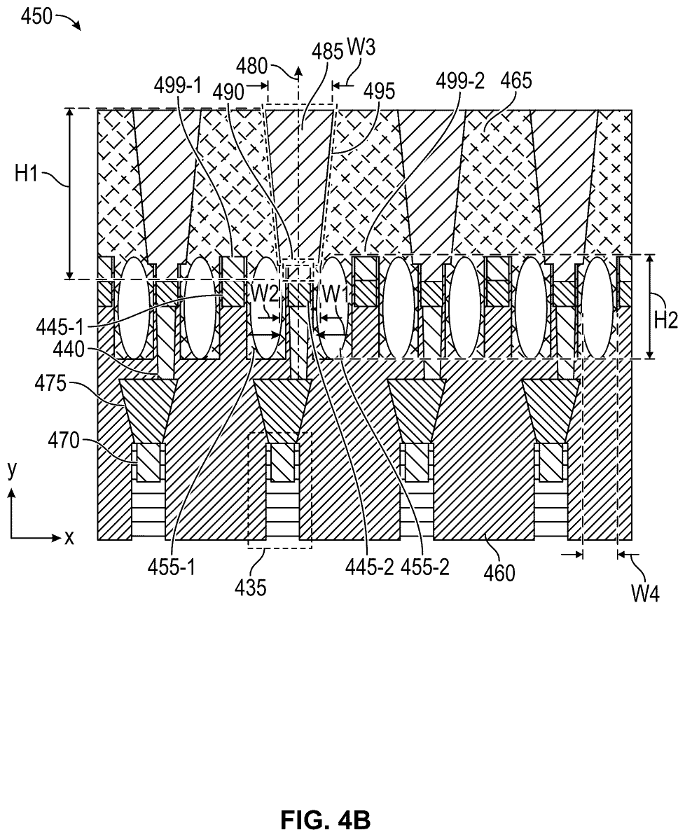

FIGS. 4A and 4B are diagrammatic views related to an example memory device structure 400 described herein. In some embodiments, the memory device structure 400 corresponds to a structure of a three-dimensional NAND memory device as described in connection with FIG. 3.

As shown in the isometric section view on the left side of FIG. 4A, the memory device structure 400 includes a memory block region 405 and a staircase region 410. The memory block region 405 and the staircase region 410 each include portions of a substrate 415 and a tiered structure 420.

In some embodiments, the substrate 415 may comprise, consist of, or consist essentially of semiconductive material. The semiconductive material may comprise, consist of, or consist essentially of silicon (e.g., polycrystalline silicon). Alternatively, and in some embodiments, the substrate 415 comprises, consists of, or consists essentially of silicon carbide, gallium nitride, or a type III-V element.

The tiered structure 420 may include conductive layers 425 that are interspersed (e.g., alternate vertically) with dielectric layers 430. Each of the conductive layers 425 may be an electrical conductor and may comprise, consist of, or consist essentially of conductive material. As used herein, a conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide).

Each of the dielectric layers 430 may be an electrical insulator and may comprise, consist of, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material).

Within the memory block region 405, one or more pillar structures 435 may penetrate through the tiered structure 420. Each of the pillar structures 435 may each include an annular distribution (e.g., layered rings) of conductive materials or insulative materials that form one or more storage cells within the memory device structure 400.

The memory device structure 400 may further include one or more interconnect structures 440 that are vertically-oriented (e.g., orthogonal to the substrate 415). In some embodiments, the interconnect structures 440 are vertical interconnect access structures (e.g., vias). Furthermore, each of the interconnect structures 440 may include one or more conductive materials as described above.

The memory device structure 400 may further include one or more conductive structures 445 that are above the tiered structure 420 and that span the memory block region 405 or the staircase region 410. The conductive structures 445 may each include one or more conductive materials. Furthermore, each of the conductive structures 445 may form a bit line of the memory device structure 400.

As shown in the detailed side section view in the right side of FIG. 4A, and as described in greater detail in connection with FIG. 4B, an interconnect region 450 of the memory device structure 400 that includes portions of the pillar structures 435, the interconnect structures 440, and the conductive structures 445 may include additional features. Such additional features (omitted from the isometric section view in the left side of FIG. 4A for clarity) may include dielectric gas regions 455 (regions including a gas with dielectric properties such as air or nitrogen, among other examples) that are between portions of the interconnect structures 440.

FIG. 4B includes a detailed section view of the interconnect region 450. As shown in FIG. 4B, the interconnect region 450 includes a dielectric region 460 and a dielectric region 465. Each of the dielectric regions 460 and 465 may be an insulative region that includes one or more dielectric materials as described above. Furthermore, the dielectric region 465 may be over or on the dielectric region 460.

As shown in FIG. 4B, the dielectric region 460 includes portions of the pillar structures 435. In some embodiments, plug structures 470 may be included as part of the pillar structures 435. Each of the plug structures 470 may include one or more conductive materials as described above. Furthermore, the plug structures 470 may electrically couple with the pillar structures 435.

Additionally, or alternatively and in some embodiments, the dielectric region 460 includes one or more contact structures 475 (e.g., lower/bottom level pillar contact structures). Each of the contact structures 475 may include a combination of one or more conductive materials as described above. In some embodiments, the contact structures 475 have a tapered cross-sectional shape. Furthermore, the contact structures 475 may be over or on the plug structures 470 to electrically couple with the pillar structures 435 through the plug structures 470.

As shown in FIG. 4B, each of the interconnect structures 440 may have a tapered shape and extend lengthwise along a coordinate direction 480 (e.g., extend vertically) toward an upper surface of the dielectric region 465 that is away from the contact structures 475. Furthermore, the interconnect structures 440 may be over or on the contact structures 475 to electrically couple with the contact structures 475.

As shown in FIG. 4B, the conductive structures 445 may be over or on the dielectric region 460. Furthermore, the conductive structures 445 may be over or on the interconnect structures 440 to electrically couple with the interconnect structures 440.

As shown in FIG. 4B, the dielectric region 465 includes one or more contact structures 485 (e.g., upper/top level bit line contact structures). The contact structures 485 may penetrate through the dielectric region 465 to one or more of the conductive structures 445.

As shown in FIG. 4B, the contact structures 485 may include rectangular portions 490 and tapered portions 495. The tapered portions 495 may be on or over the rectangular portions 490 to electrically couple with the rectangular portions 490. In other words, each of the contact structures 485 may include an upper portion that has a tapered cross-sectional shape (e.g., the tapered portions 495) that electrically couples with a lower portion that has an approximately rectangular cross-sectional shape (e.g., the rectangular portions 490).

In some embodiments, and as shown in FIG. 4B, each of the rectangular portions 490 and the conductive structures 445 has a same approximate width W1. Additionally, or alternatively and in some embodiments, a width W2 of a base of each of the tapered portions 495 is greater than the width W1. Additionally, alternatively and in some embodiments, a width W3 of a top of each of the tapered portions 495 is greater than the width W1 or the width W2.

In some embodiments, and as shown in FIG. 4B, the contact structures 485 extend lengthwise along the coordinate direction 480 (e.g., extend vertically) toward an upper surface of the dielectric region 465 that is away from the conductive structures 445. Furthermore, the contact structures may extend lengthwise a height H1, where the height H1 is substantially greater than width W2 or the width W3. In other words, the contact structures 485 may be elongated, vertically-oriented contact structures. In contrast to another memory array structure in which contact structures are laterally-oriented (e.g., extend horizontally), an overall signaling length of integrated circuitry (e.g., including the contact structures 485 having the height H1) may be less, to reduce parasitic degradation and improve an electrical performance.

As shown in FIG. 4B, the dielectric region 465 includes one or more hard mask structures 499 that are over or on the conductive structures 445. The hard mask structures 499 may each include a combination of one or more dielectric materials as described above.

As shown in FIG. 4B, the dielectric gas regions 455 may extend lengthwise along the coordinate direction 480 (e.g., extend vertically). Furthermore, the dielectric gas regions 455 may extend a height H2, where the height H2 is substantially greater than a width W4 of the dielectric gas regions 455. In other words, the dielectric gas regions 455 may be elongated, vertically-oriented dielectric gas regions. In contrast to another memory array structure in which the dielectric region 465 excludes the hard mask structures 499, the height H2 may be extended to provide greater electrical isolation for portions of the interconnect structures 440, the conductive structures 445, or the contact structures 485, to reduce parasitic degradation and satisfy an electrical performance threshold within the interconnect region 450.

In some embodiments, the dielectric gas regions 455 are extended to overlap (e.g., include portions that are parallel to or overlap) portions of the interconnect structures 440, portions of the conductive structures 445 (e.g., including entireties of the conductive structures 445), portions of the contact structures 485, or portions of the hard mask structures 499 (e.g., including entireties of the hard mask structures 499).

Additionally, or alternatively and in some embodiments, portions or sub regions of one or more of the dielectric gas regions 455 may be between facing surfaces of two or more of the hard mask structures 499. For example, and as shown in FIG. 4B, an upper end region of the dielectric gas region 455-1 (or the dielectric gas region 455-2) is between facing surfaces of the hard mask structures 499-1 and 499-2.

Additionally, or alternatively, in some embodiments, one or more of the hard mask structures 499 may be proximate (e.g., adjacent to) an outer edge of one or more of the dielectric gas regions 455. For example, and as shown in FIG. 4B, the hard mask structure 499-1 is proximate to an outer edge of the dielectric gas region 455-1 and the hard mask structure 499-2 is proximate to an outer edge of the dielectric gas region 455-2.

As indicated above, FIGS. 4A and 4B are provided as an example. Other examples may differ from what is described with regards to FIGS. 4A and 4B.

As described in connection with FIGS. 1 through 4B, and in some embodiments, a semiconductor device (e.g., the memory device structure 400) includes a first contact structure (e.g., the contact structure 475) extending along a coordinate direction (e.g., the coordinate direction 480), an interconnect structure (e.g., the interconnect structure 440) formed on the first contact structure, a conductive structure (e.g., the conductive structure 445-2) formed on the interconnect structure, a second contact structure (e.g., the contact structure 485) formed on the conductive structure and extending along the coordinate direction, a first dielectric gas region (e.g., the dielectric gas region 455-1) having an extended region, and a second dielectric gas region (e.g., the dielectric gas region 455-2) having an extended region. In some embodiments, the interconnect structure includes a portion formed between the first and second dielectric gas regions and the conductive structure includes a portion formed between the first and second dielectric gas regions. In some embodiments, the second contact structure includes a portion overlapping the extended region of the first dielectric gas region and the extended region of the second dielectric gas region.

Additionally, or alternatively, in some embodiments, an apparatus (e.g., the memory device structure 400) includes a first bit line structure (e.g., the conductive structure 445-1), a hard mask structure (e.g., the hard mask structure 499-1) that is directly on the first bit line structure, and a second bit line structure (e.g., the conductive structure 445-2). The apparatus further includes an elongated, vertically-oriented contact structure (e.g., the contact structures 485) that is directly on the second bit line structure and an elongated, vertically-oriented dielectric gas region (e.g., the dielectric gas region 455-1) that is between the first bit line structure and the second bit line structure and that includes an upper end region that overlaps the hard mask structure and the elongated, vertically-oriented contact structure.

In some embodiments, a semiconductor device (e.g., a NAND memory device) may include the integrated assembly or apparatus. In contrast to a semiconductor device that includes an integrated assembly or apparatus having laterally-oriented contact structures, the semiconductor device that includes the vertically-oriented contact structures may facilitate extended dielectric gas regions (e.g., dielectric gas regions) or a reduced signaling length to reduce parasitic degradation and satisfy a performance threshold. Additionally, or alternatively, a footprint of the semiconductor device may be reduced.

In this way, a quality, a reliability, or a performance of a semiconductor device is improved relative to another semiconductor device formed using the laterally-oriented contact structures. By improving the quality, reliability, or the performance of the semiconductor device, and by reducing the footprint of the semiconductor device, an amount of resources used to support a market consuming the semiconductor device (e.g., labor, semiconductor manufacturing tools, raw materials, or computing resources) is reduced.

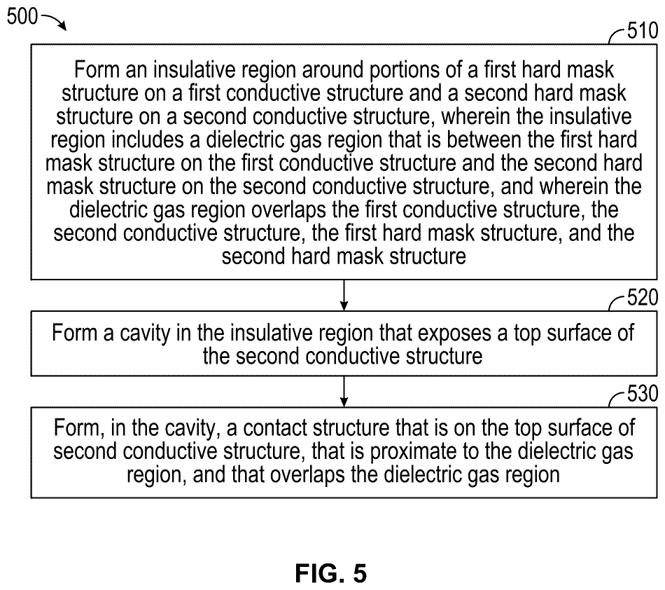

FIG. 5 is a flowchart of an example method 500 of forming an integrated assembly or memory device having an interconnect region (e.g., the interconnect region 450) that includes a contact structure (e.g., the contact structures 485) described herein. In some embodiments, and as described in greater detail in connection with FIGS. 5A-5D, one or more process blocks of FIG. 5 may be performed by various semiconductor manufacturing equipment.

As shown in FIG. 5, the method 500 may include forming an insulative region (e.g., the dielectric region 465) around portions of a first hard mask structure (e.g., the hard mask structure 499-1) on a first conductive structure (e.g., the conductive structure 445-1) and a second hard mask structure on a second conductive structure (e.g., the conductive structure 445-2), wherein the insulative region includes a dielectric gas region (e.g., the dielectric gas region 455-1) that is between the first hard mask structure on the first conductive structure and the second hard mask structure on the second conductive structure, and wherein the dielectric gas region overlaps the first conductive structure, the second conductive structure, the first hard mask structure, and the second hard mask structure (block 510). As further shown in FIG. 5, the method 500 may include forming a cavity in the insulative region that exposes a top surface of the second conductive structure (block 520). As further shown in FIG. 5, the method 500 may include forming, in the cavity, a contact structure (e.g., the contact structures 485) that is on the top surface of second conductive structure, that is proximate to the dielectric gas region, and that overlaps the dielectric gas region (block 530).

The method 500 may include additional aspects, such as any single aspect or any combination of aspects described below or in connection with one or more other methods described elsewhere herein.

In a first aspect, forming the cavity includes forming a first portion of the cavity in the insulative region that exposes a top surface of the second hard mask structure, and forming a second portion of the cavity that extends from the first portion to expose the top surface of the second conductive structure.

In a second aspect, alone or in combination with the first aspect, forming the first portion includes forming the first portion using a dry etch operation.

In a third aspect, alone or in combination with one or more of the first and second aspects, forming the second portion includes forming the second portion using a wet etch operation that removes a portion of the second hard mask structure.

In a fourth aspect, alone or in combination with one or more of the first through third aspects, forming the second portion includes forming the second portion using a wet etch operation that removes an entirety of the second hard mask structure.

In a fifth aspect, alone or in combination with one or more of the first through fourth aspects, forming the contact structure includes forming a portion (e.g., the rectangular portions 490) having an approximately rectangular cross section that is on the top surface, that is proximate to the dielectric gas region, and that overlaps the dielectric gas region.

In a sixth aspect, alone or in combination with one or more of the first through fifth aspects, the portion is a first portion, and forming the contact structure further includes forming a second portion (e.g., the tapered portions 495) having a tapered cross section that is on the first portion and that extends from the first portion to a surface of the insulative region.

In a seventh aspect, alone or in combination with one or more of the first through sixth aspects, the method 500 includes planarizing a top surface of the contact structure and the insulative region.

Although FIG. 5 shows example blocks of the method 500, in some embodiments, the method 500 may include additional blocks, fewer blocks, different blocks, or differently arranged blocks than those depicted in FIG. 5. In some embodiments, the method 500 may include forming the contact structures 485, an integrated assembly that includes the contact structures 485, any part described herein of the contact structures 485, or any part described herein of an integrated assembly that includes the contact structures 485. For example, the method 500 may include forming one or more of the memory device structure 400, the memory block region 405, the conductive structures 445, the dielectric gas regions 455, the rectangular portions 490, the tapered portions 495, or the hard mask structures 499.

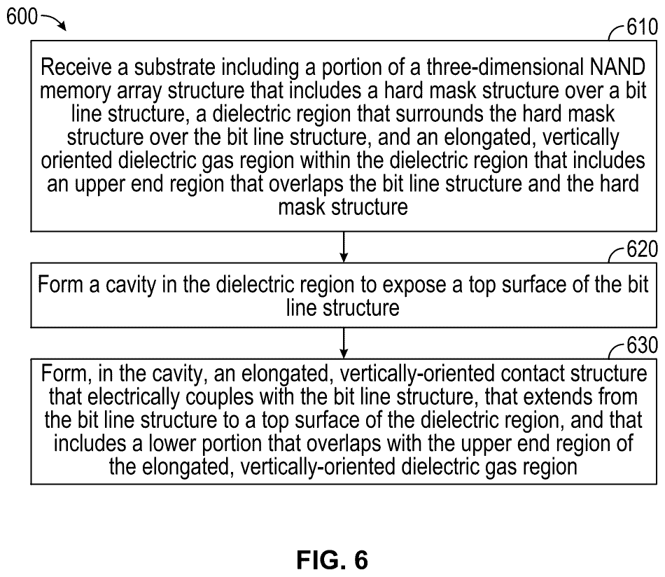

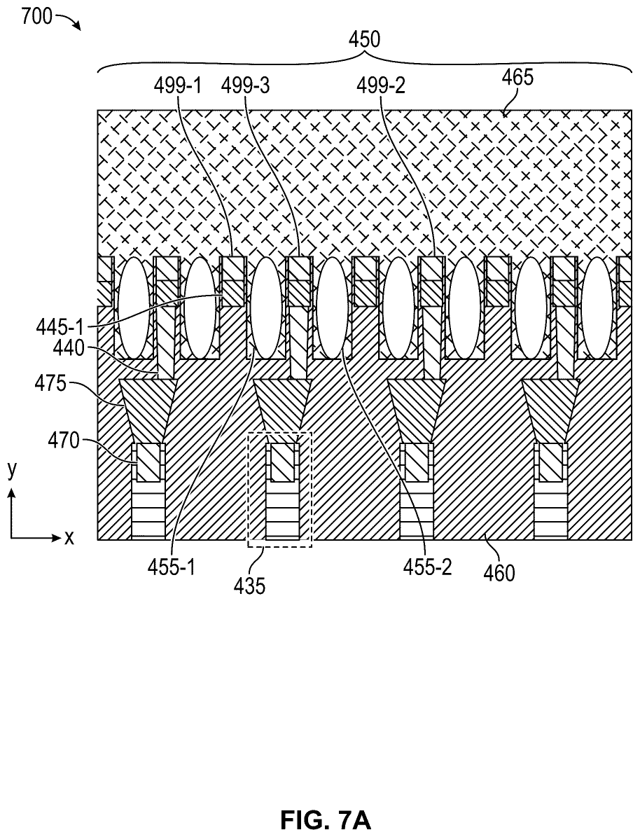

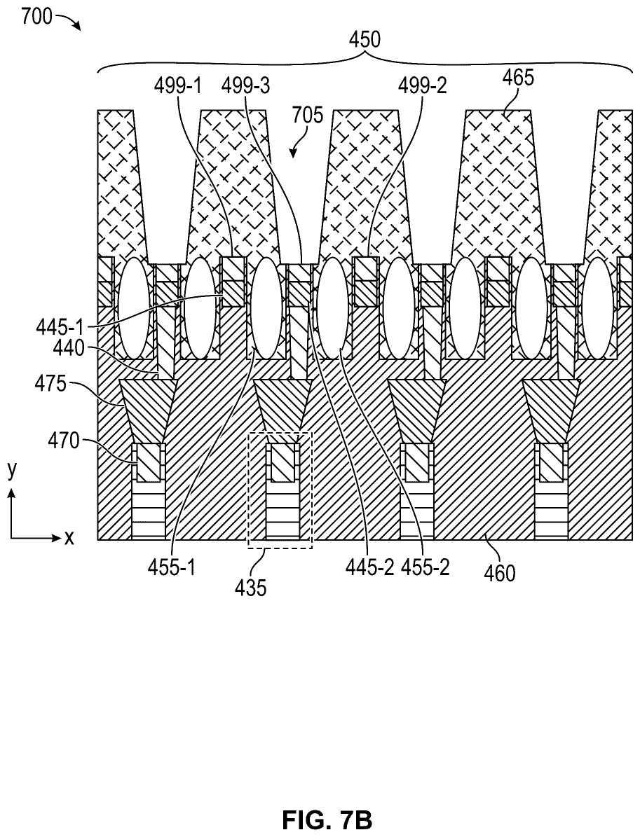

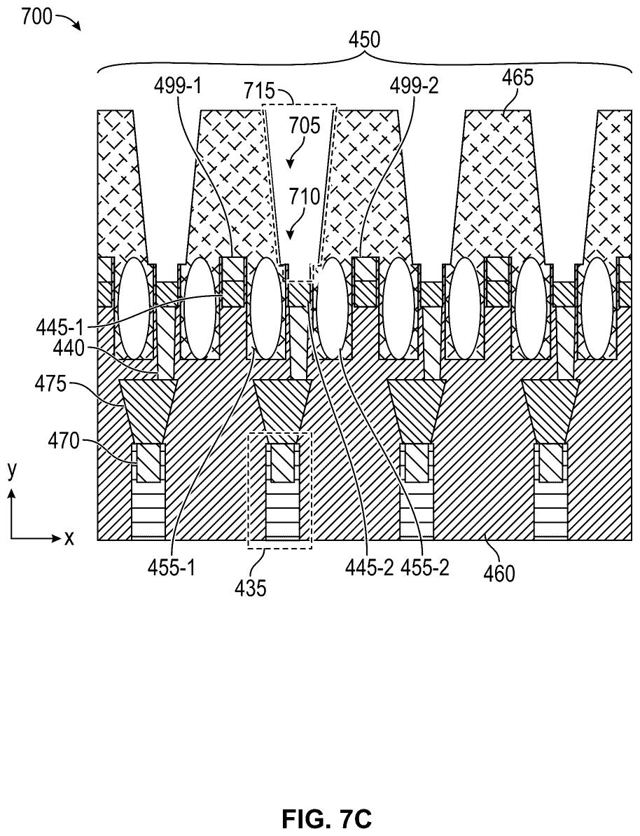

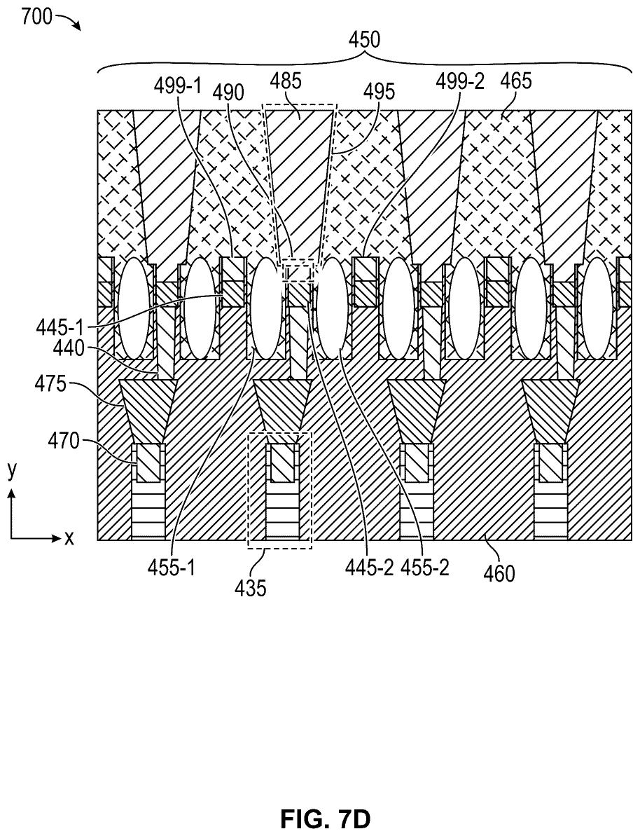

FIG. 6 is a flowchart of an example method 600 of forming an integrated assembly or memory device having an interconnect region (e.g., the interconnect region 450) that includes a contact structure (e.g., the contact structures 485) described herein. In some embodiments, and as described in greater detail in connection with FIGS. 7A-7D, one or more process blocks of FIG. 6 may be performed by various semiconductor manufacturing equipment.

As shown in FIG. 6, the method 600 may include receiving a substrate (e.g., the substrate 415) including a portion of a three-dimensional NAND memory array structure (e.g., a portion of the memory device structure 400) that includes a hard mask structure over a bit line structure (e.g., the conductive structure 445-2), a dielectric region (e.g., the dielectric region 465) that surrounds the hard mask structure over the bit line structure, and an elongated, vertically-oriented dielectric gas region (e.g., the dielectric gas region 455-1) within the dielectric region that includes an upper end region that overlaps the bit line structure and the hard mask structure (block 610). As further shown in FIG. 6, the method 600 may include forming a cavity in the dielectric region to expose a top surface of the bit line structure (block 620). As further shown in FIG. 6, the method 600 may include forming, in the cavity, an elongated, vertically-oriented contact structure (e.g., the contact structure 485) that electrically couples with the bit line structure, that extends from the bit line structure to a top surface of the dielectric region, and that includes a lower portion (e.g., the tapered portions 495) that overlaps with the upper end region of the elongated, vertically-oriented dielectric gas region (block 630).

The method 600 may include additional aspects, such as any single aspect or any combination of aspects described below or in connection with one or more other methods described elsewhere herein.

In a first aspect, forming the cavity includes removing at least a portion of the hard mask structure to expose the top surface of the bit line structure.

In a second aspect, alone or in combination with the first aspect, the elongated, vertically-oriented dielectric gas region is a first elongated, vertically-oriented dielectric gas region, the upper end region is a first upper end region, and forming the cavity includes forming the cavity between the first upper end region of the first elongated, vertically-oriented dielectric gas region and a second upper end region of a second elongated, vertically-oriented dielectric gas region (e.g., the dielectric gas region 455-2).

In a third aspect, alone or in combination with one or more of the first and second aspects, the hard mask structure is a first hard mask structure, and forming the elongated, vertically-oriented contact structure includes forming the lower portion between facing surfaces of a second hard mask structure (e.g., the hard mask structure 499-1) and a third hard mask structure (e.g., the hard mask structure 499-2).

Although FIG. 6 shows example blocks of the method 600, in some embodiments, the method 600 may include additional blocks, fewer blocks, different blocks, or differently arranged blocks than those depicted in FIG. 4. In some embodiments, the method 600 may include forming the interconnect region 450 that includes the contact structures 485, an integrated assembly that includes the interconnect region 450 that includes the contact structures 485, any part described herein of the interconnect region 450 that includes the contact structures 485, or any part described herein of an integrated assembly that includes the interconnect region 450 that includes the contact structures 485. For example, the method 600 may include forming one or more of the memory device structure 400, the memory block region 405, the conductive structures 445, the dielectric gas regions 455, the rectangular portions 490, the tapered portions 495, or the hard mask structures 499.

FIGS. 7A through 7D are diagrammatic views showing formation of portions of an interconnect region (e.g., the interconnect region 450) that includes a contact structure (e.g., the contact structures 485) described at stages of an example process 700 described herein. In some embodiments, the process 700 described below in connection with FIGS. 7A through 7D may correspond to the method 500, one or more blocks of the method 500, the method 600, or one or more blocks of the method 600. However, the process described below is an example, and other example processes may be used to form the tiered structure, an integrated assembly that includes the tiered structure, or one or more parts of an integrated assembly including the interconnect array structure.

As shown in FIG. 7A, the process 700 may include receiving a device, apparatus, or substrate (e.g., the substrate 415) including one or more structures of the interconnect region 450 (e.g., the pillar structures 435, the interconnect structures 440, the conductive structures 445, the dielectric gas regions 455, the dielectric region 460, the plug structures 470, the contact structures 475, and or the hard mask structures 499). As further shown in FIG. 7A, the process 700 may further include forming the dielectric region 465 over or around portions of the conductive structures 445 or the hard mask structures 499. In some embodiments, techniques to form the dielectric region 465 include a semiconductor manufacturing tool (e.g., a deposition tool) performing a deposition operation.

As shown in FIG. 7B, the process 700 includes forming cavities 705 through the dielectric region 465. Each of the cavities 705 may expose a top surface of one of the hard mask structures 499. For example, and as shown in FIG. 7B, a top surface of the hard mask structure 499-3 is exposed. In some embodiments, techniques to form the cavities 705 include a semiconductor manufacturing tool (e.g., an etch tool) performing a dry etch operation.

As shown in FIG. 7C, the process 700 includes forming cavities 710 that extend from the cavities 705. Each of the cavities 710 may expose a top surface of one of the conductive structures 445. For example, and as shown in FIG. 7C, a top surface of the conductive structure 445-2 is exposed. In some embodiments, techniques to form the cavities 710 include a semiconductor manufacturing tool (e.g., an etch tool) performing a wet etch operation. The wet etch operation may remove portions or entireties of one or more of the hard mask structures 499. For example, and as shown in FIG. 7C, an entirety of the hard mask structure 499-3 is removed.

As shown in FIG. 7C, the cavities 705 and the cavities 710 may combine to form cavities 715. The cavities 705 may be first portions (e.g., tapered portions) of the cavities 715 and the cavities 710 may be second portions (e.g., rectangular portions) of the cavities 715.

As shown in FIG. 7D, the process 700 includes forming the contact structures 485 in the cavities 715. In some embodiments, techniques to form the contact structures 485 include a semiconductor manufacturing tool (e.g., a deposition tool) performing a deposition operation. Additionally, forming the contact structures 485 may include planarizing the contact structures 485 after deposition. In some embodiments, techniques to planarize the contact structures 485 include a semiconductor manufacturing tool (e.g., a planarization tool) performing a chemical/mechanical planarization (CMP) operation after deposition of the contact structures 485.

As indicated above, FIGS. 7A-7D are provided as an example. Other examples may differ from what is described with regard to FIGS. 7A-7D.

In some embodiments, a semiconductor device includes a first contact structure extending along a coordinate direction; an interconnect structure formed on the first contact structure; a conductive structure formed on the interconnect structure; a second contact structure formed on the conductive structure and extending along the coordinate direction; a first dielectric gas region having an extended region; and a second dielectric gas region having an extended region, wherein the interconnect structure includes a portion formed between the first and second dielectric gas regions and the conductive structure includes a portion formed between the first and second dielectric gas regions, and wherein the second contact structure includes a portion overlapping the extended region of the first dielectric gas region and the extended region of the second dielectric gas region.

In some embodiments, an apparatus includes a first bit line structure; a hard mask structure that is directly on the first bit line structure; a second bit line structure; an elongated, vertically-oriented contact structure that is directly on the second bit line structure; and an elongated, vertically-oriented dielectric gas region that is between the first bit line structure and the second bit line structure and that includes an upper end region that overlaps the hard mask structure and the elongated, vertically-oriented contact structure.

In some embodiments, a method includes forming an insulative region around portions of a first hard mask structure on a first conductive structure and a second hard mask structure on a second conductive structure, wherein the insulative region includes a dielectric gas region that is between the first hard mask structure on the first conductive structure and the second hard mask structure on the second conductive structure, and wherein the dielectric gas region overlaps the first conductive structure, the second conductive structure, the first hard mask structure, and the second hard mask structure; forming a cavity in the insulative region that exposes a top surface of the second conductive structure; and forming, in the cavity, a contact structure that is on the top surface of second conductive structure, that is proximate to the dielectric gas region, and that overlaps the dielectric gas region.

In some embodiments, a method includes receiving a substrate including a portion of a three-dimensional NAND memory array structure that includes a hard mask structure over a bit line structure, a dielectric region that surrounds the hard mask structure over the bit line structure, and an elongated, vertically-oriented dielectric gas region within the dielectric region that includes an upper end region that overlaps the bit line structure and the hard mask structure; forming a cavity in the dielectric region to expose a top surface of the bit line structure; and forming, in the cavity, an elongated, vertically-oriented contact structure that electrically couples with the bit line structure, that extends from the bit line structure to a top surface of the dielectric region, and that includes a lower portion that overlaps with the upper end region of the elongated, vertically-oriented dielectric gas region.

The foregoing disclosure provides illustration and description but is not intended to be exhaustive or to limit the embodiments to the precise forms disclosed. Modifications and variations may be made in light of the above disclosure or may be acquired from practice of the embodiments described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, or assembly in use or operation in addition to the orientations depicted in the figures. A structure or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, the term “formed” may, depending on the context, refer to a state or a position of a first feature relative to a second feature, and does not imply any specific method or sequence of formation. As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims or disclosed in the specification, these combinations are not intended to limit the disclosure of embodiments described herein. Many of these features may be combined in ways not specifically recited in the claims or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “cither” or “only one of”).

What is claimed is:

1. A semiconductor device, comprising:
a first contact structure extending along a coordinate direction;
an interconnect structure formed on the first contact structure;
a conductive structure formed on the interconnect structure;
a second contact structure formed on the conductive structure and extending along the coordinate direction;
a first dielectric gas region having an extended region; and
a second dielectric gas region having an extended region,
wherein the interconnect structure includes a portion formed between the first and second dielectric gas regions and the conductive structure includes a portion formed between the first and second dielectric gas regions, and
wherein the second contact structure includes a portion overlapping the extended region of the first dielectric gas region and the extended region of the second dielectric gas region.

2. The semiconductor device of claim 1, wherein the portion of the second contact structure comprises:
an approximately rectangular cross-sectional shape.

3. The semiconductor device of claim 1, wherein the portion of the second contact structure is a first portion, and
wherein the second contact structure further comprises:
a second portion that is on the first portion, that electrically couples with the first portion, and that extends away from the first portion along the coordinate direction.

4. The semiconductor device of claim 3, wherein the second portion comprises:
a tapered cross-sectional shape.

5. The semiconductor device of claim 1, further comprising:
a first hard mask structure that is proximate to an outer edge of the first dielectric gas region, and a second hard mask structure that is proximate to an outer edge of the second dielectric gas region.

6. The semiconductor device of claim 5, wherein the first dielectric gas region overlaps the first hard mask structure along the coordinate direction, and
wherein the second dielectric gas region overlaps the second hard mask structure along the coordinate direction.

7. An apparatus, comprising:
a first bit line structure;
a hard mask structure that is directly on the first bit line structure;
a second bit line structure;
an elongated, vertically-oriented contact structure that is directly on the second bit line structure; and
an elongated, vertically-oriented dielectric gas region that is between the first bit line structure and the second bit line structure and that includes an upper end region that overlaps the hard mask structure and the elongated, vertically-oriented contact structure.

8. The apparatus of claim 7, wherein the elongated, vertically-oriented contact structure extends from a surface of the second bit line structure to a surface of a dielectric region that includes the elongated, vertically-oriented contact structure.

9. The apparatus of claim 8, wherein the elongated, vertically-oriented contact structure is above a dielectric region.

10. The apparatus of claim 8, wherein the first bit line structure, the hard mask structure, the second bit line structure, the elongated, vertically-oriented contact structure, and the elongated, vertically-oriented, dielectric gas region are part of a memory block region of a three-dimensional NAND memory device.

11. The apparatus of claim 8, wherein the elongated, vertically-oriented contact structure comprises:
a lower portion having an approximately rectangular cross-sectional shape, and
an upper portion having a tapered cross-sectional shape.

12. The apparatus of claim 11, wherein width of a base of the upper portion is greater than a width of the lower portion.

13. The apparatus of claim 11, wherein a width of the lower portion and a width of the bit line structure are a same approximate width.

14. A method, comprising:
forming an insulative region around portions of a first hard mask structure on a first conductive structure and a second hard mask structure on a second conductive structure,
wherein the insulative region includes a dielectric gas region that is between the first hard mask structure on the first conductive structure and the second hard mask structure on the second conductive structure, and
wherein the dielectric gas region overlaps the first conductive structure, the second conductive structure, the first hard mask structure, and the second hard mask structure;
forming a cavity in the insulative region that exposes a top surface of the second conductive structure; and
forming, in the cavity, a contact structure that is on the top surface of second conductive structure, that is proximate to the dielectric gas region, and that overlaps the dielectric gas region.

15. The method of claim 14, wherein forming the cavity includes:
forming a first portion of the cavity in the insulative region that exposes a top surface of the second hard mask structure, and
forming a second portion of the cavity that extends from the first portion to expose the top surface of the second conductive structure.

16. The method of claim 15, wherein forming the first portion includes:
forming the first portion using a dry etch operation.

17. The method of claim 15, wherein forming the second portion includes:
forming the second portion using a wet etch operation that removes a portion of the second hard mask structure.

18. The method of claim 15, wherein forming the second portion includes:
forming the second portion using a wet etch operation that removes an entirety of the second hard mask structure.

19. The method of claim 14, wherein forming the contact structure includes:
forming a portion having an approximately rectangular cross section that is on the top surface, that is proximate to the dielectric gas region, and that overlaps the dielectric gas region.

20. The method of claim 19, wherein the portion is a first portion, and wherein forming the contact structure further includes:
forming a second portion having a tapered cross section that is on the first portion and that extends from the first portion to a surface of the insulative region.

21. The method of claim 14, further comprising:
planarizing a top surface of the contact structure and the insulative region.

22. A method, comprising:
receiving a substrate including a portion of a three-dimensional NAND memory array structure that includes a hard mask structure over a bit line structure, a dielectric region that surrounds the hard mask structure over the bit line structure, and an elongated, vertically-oriented dielectric gas region within the dielectric region that includes an upper end region that overlaps the bit line structure and the hard mask structure;
forming a cavity in the dielectric region to expose a top surface of the bit line structure; and
forming, in the cavity, an elongated, vertically-oriented contact structure that electrically couples with the bit line structure, that extends from the bit line structure to a top surface of the dielectric region, and that includes a lower portion that overlaps with the upper end region of the elongated, vertically-oriented dielectric gas region.

23. The method of claim 22, wherein forming the cavity includes:
removing at least a portion of the hard mask structure to expose the top surface of the bit line structure.

24. The method of claim 22, wherein the elongated, vertically-oriented dielectric gas region is a first elongated, vertically-oriented dielectric gas region, wherein the upper end region is a first upper end region, and
wherein forming the cavity includes:
forming the cavity between the first upper end region of the first elongated, vertically-oriented dielectric gas region and a second upper end region of a second elongated, vertically-oriented dielectric gas region.

25. The method of claim 22, wherein the hard mask structure is a first hard mask structure, and
wherein forming the elongated, vertically-oriented contact structure includes:
forming the lower portion between facing surfaces of a second hard mask structure and a third hard mask structure.
